(19) United States
(12) Patent Application Publication
(10) Pub. No.: US 2025/0096016 A1
(43) Pub. Date: Mar. 20, 2025

(54) POSITIONING DEVICE AND MOUNTING DEVICE USING SAME

(71) Applicant: TORAY ENGINEERING CO., LTD., Tokyo (JP)

(72) Inventors: Kenji HAMAKAWA, Otsu-shi, Shiga (JP); Takashi HARE, Otsu-shi, Shiga (JP); Kensuke TASHIMA, Otsu-shi, Shiga (JP); Shigeru TOHNO, Otsu-shi, Shiga (JP); Ken KITAMURA, Otsu-shi, Shiga (JP)

(21) Appl. No.: 18/726,891

(22) PCT Filed: Dec. 22, 2022
(86) PCT No.: PCT/JP2022/047258

§ 371 Date: Jul. 5, 2024

(30) Foreign Application Priority Data
Jan. 11, 2022 (JP) 2022-002055

(51) Int. Cl. H01L 21/67; H01L 21/60; H01L 21/687

(52) U.S. Cl. CPC H01L 21/67144; H01L 21/60; H01L 21/67259; H01L 21/68721; H01L 21/68785; H01L 21/67098

(57) ABSTRACT

A positioning device is provided for determining a relative position between a substrate and a processing unit that is configured to perform an attachment process, when performing the attachment process at a prescribed position of the substrate. The positioning device comprises a substrate table configured to hold the substrate, a processing position movement mechanism including a driving unit configured to move the substrate table and the processing unit relative to each other, and a braking unit configured to restrict movement, caused by the driving unit, of at least one of the substrate table and the processing unit, and a control unit connected to the driving unit and the braking unit. The control unit is configured to restrict, by using the braking unit, the movement of the at least one of the substrate table and the processing unit during the attachment process.

### CROSS-REFERENCE TO RELATED APPLICATIONS

This application is a U.S. National stage of International Application No. PCT/JP2022/047258 filed on Dec. 22, 2022. This application claims priority to Japanese Patent Application No. 2022-002055 filed on Jan. 11, 2022 with Japan Patent Office.

### BACKGROUND

### Field of the Invention

The present invention relates to a positioning device for determining relative positions of a processing means and a substrate, when performing an attachment process at a prescribed position of the substrate, and to a mounting device that uses the positioning device.

### Background Information

Substrates used in mounting devices for mounting a plurality of chip components on substrates, such as wiring substrates, are growing larger in size. With respect to such size increases of substrates, a method of moving a bonding head to each mounting location could be employed to reduce the range of movement of the substrate, thereby avoiding an increase in the size of the device.

### SUMMARY

However, when attempting to move a bonding head 14 in a bonding device such as that shown in FIG. 17, the bonding head 14 would be held in a cantilevered state. When attempting to pressure-bond a chip component C onto a substrate S at a pressure F using such a cantilevered bonding head 14, tilt is generated in the bonding head 14 from the state of FIG. 18 to the state shown in FIG. 19. As a result, as shown in FIG. 19, the portion of the bonding head 14 that holds the chip component C may be positionally misaligned in the +Y direction at the time of mounting.

Thus, in a case in which high-precision mounting is required even for large substrates, a pressurization shaft of the bonding head 14 (of an elevating and pressing unit 13) is fixed to a gate-shaped frame 300, as shown in FIG. 20, and alignment of the chip component and the substrate is performed by moving (positional adjustment) a substrate stage 2.

When mounting chip components onto large substrates, high speed in addition to high precision is required. For this reason, it is necessary to align and move the substrate stage 2 at a high speed, using a configuration of a mounting device such as that shown in FIG. 20.

However, because the size of the substrate stage 2 for moving large substrates is also increasing, it is becoming difficult to perform alignment at a high speed.

Regarding increasing the speed of alignment, the present applicant has invented a method of performing precise alignment using a bonding tool (attachment tool), provided in a bonding head, with the positions of the substrate stage and the bonding head fixed, after a stage movement control step (for example, Japanese Laid-Open Patent Application Publication No. H08-288337 (Patent Document 1)).

However, the content described in Patent Document 1 may be improved to simultaneously achieve the recent demands for further increases in the size of the substrate, improvements in the required precision to the submicron level, and reduction in the takt time.

One object is to provide a positioning device and a mounting device that make it possible to mount a plurality of chip components onto a large substrate with high precision and high speed.

In order to solve the problem described above, according to a first aspect, a positioning device for determining relative positions of a substrate and a processing means that performs an attachment process, when performing the attachment process at a prescribed position of the substrate, comprising: a substrate table for holding the substrate; a processing position movement mechanism that includes a driving means for moving the substrate table and the processing means relative to each other and a braking means for restricting the movement, caused by the driving means, of at least one of the substrate table and the processing means; and a control unit connected to the driving means and the braking means, wherein the control unit restricts, by using the braking means, the movement of at least one of the substrate table and the processing means during the attachment process.

According to a second aspect, with the positioning device according to the first aspect, the processing position movement mechanism has a slide rail, and the relative movement of the substrate table and the processing means caused by the driving means is performed along the slide rail, and the braking means restricts movement by partially gripping the slide rail.

According to a third aspect, the positioning device according to the second aspect, further comprises a length measurement means for disposing a position detection unit along the slide rail, wherein the position detection unit is a positioning device provided near the braking means.

According to a fourth aspect, the positioning device according to any one of the first to the third aspects further comprises a timer that is connected to the control unit and that measures the time after the braking means is operated, wherein the control unit is a positioning device that determines that the attachment process can be started when the time measured by the timer reaches a prescribed value.

According to a fifth aspect, with the positioning device according to any one of the first to the fourth aspects, the control unit operates the braking means and then turns off the power supply to the driving means.

According to a sixth aspect, with the positioning device according to any one of the first to the fourth aspects, a servo motor is used as the driving means, and the control unit operates the braking means and then changes the responsiveness of the servo motor.

According to a seventh aspect, with a mounting device that uses the positioning device according to any one of the first to the sixth aspects, the attachment process is mounting in which a chip component is arranged on the substrate and pressure-bonded, and the processing means is provided with an attachment tool that uses suction to hold the chip component, a bonding head that holds the attachment tool, and an elevating and pressing unit that is linked to the bonding head and can control the position of the bonding head in the up and down direction as well as control the pressure.

According to an eighth aspect, the mounting device according to the seventh aspect further comprises a recognition mechanism that acquires position information of a substrate recognition mark of the substrate and of a chip recognition mark of the chip component, wherein the bonding head has a tool position adjustment means that can finely adjust the position of the attachment tool in an in-plane direction of the chip component, the positioning device determines the relative position of the substrate with respect to the bonding head, and in a state in which the bonding head is lowered and the chip component held by the attachment tool is brought close the substrate, the recognition mechanism acquires position information of the substrate recognition mark and of the chip recognition mark, and the tool position adjustment means precisely aligns the chip component to the mounting location of the substrate.

By means of the present disclosure, it becomes possible for the mounting device to align chip components and large substrates with high speed and high precision, and to perform mounting of chip components onto large substrates with high precision and in a short takt time.

### BRIEF DESCRIPTION OF THE DRAWINGS

FIG. 1 is a schematic diagram of a mounting device according to an embodiment of the present disclosure.

FIG. 2 is a diagram explaining the main constituent elements according to the embodiment of the present disclosure.

FIGS. 3A, 3B, 3C and 3D are diagrams explaining the relationship between a position detection unit and braking locations of the positioning device according to the embodiment of the present disclosure.

FIGS. 4A and 4B are diagrams explaining an optical configuration according to the embodiment of the present disclosure, with FIG. 4A showing a front view of the optical configuration, and FIG. 4B showing a side view of the optical configuration.

FIG. 5 is a block diagram showing a control system according to the embodiment of the present disclosure.

FIG. 6 is a diagram showing a step in which the mounting device according to the embodiment of the present disclosure mounts a chip component on a substrate.

FIG. 7 is a diagram showing various procedures for fixing a substrate stage in the mounting device according to the embodiment of the present disclosure.

FIG. 8 is a diagram explaining a state in which a chip recognition mark is recognized using an imaging means immediately after being handed over to a bonding head in the mounting device according to the embodiment of the present disclosure.

FIG. 9 is a diagram explaining a state in which a substrate recognition mark and the chip recognition mark are recognized using the imaging means in the mounting device according to the embodiment of the present disclosure.

FIGS. 10A and 10B are diagrams explaining an optical configuration according to a modified example of the embodiment of the present disclosure, with FIG. 10A showing a front view of the optical configuration, and FIG. 10B showing a side view of the optical configuration.

FIG. 11 is a diagram explaining a state in which the substrate recognition mark and the chip recognition mark are recognized using different imaging means in the mounting device according to a modified example of the embodiment of the present disclosure.

FIG. 12 is a diagram showing a step in which a mounting device according to a comparative example mounts a chip component on a substrate.

FIG. 13 is a schematic diagram of a modified example of the mounting device according to the embodiment of the present disclosure, in which the mounting device has a plurality of bonding heads.

FIG. 14 is a schematic diagram showing the main constituent elements of a mounting device according to an embodiment in which the present disclosure is applied to flip chip mounting.

FIG. 15 is a schematic diagram of a mounting device according to a second embodiment of the present disclosure.

FIG. 16 is a schematic diagram of a mounting device according to a third embodiment of the present disclosure.

FIG. 17 is a schematic diagram of a mounting device according to a comparative example.

FIG. 18 is a diagram explaining the reaction force that is applied to the device when pressure application is performed in a mounting device according to a comparative example.

FIG. 19 is a diagram explaining the effect of the reaction force when pressure application is performed in a mounting device according to a comparative example.

FIG. 20 is a schematic diagram explaining one example of a high-precision mounting device.

### DETAILED DESCRIPTION OF EMBODIMENTS

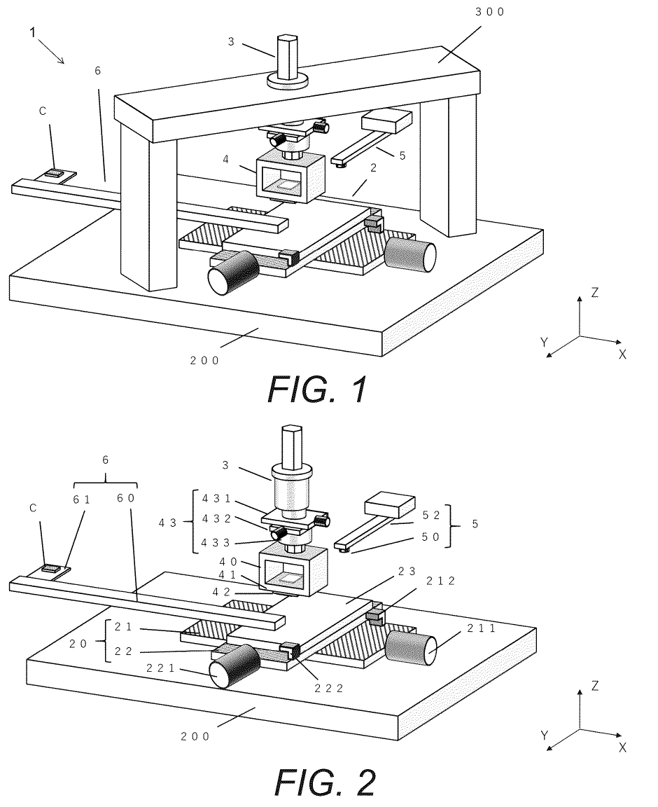

Embodiments of the present disclosure will be described below with reference to the drawings. FIG. 1 is a schematic diagram of a mounting device 1 that uses a positioning device according to an embodiment of the present disclosure.

A mounting device sequentially mounts chip components on a plurality of mounting locations provided on a substrate, such as a wiring substrate, and the mounting device 1 of FIG. 1 is configured to perform face-up mounting, in which mounting is performed in a state in which the electrode surface of the chip component and the electrode surface of the substrate are facing in the same direction.

In the mounting device 1 shown in FIG. 1, a substrate stage 2 and a gate-shaped frame 300 are provided on a base 200. The substrate stage 2 has the function of holding a substrate and moving the substrate in an in-plane direction of the substrate. An elevating and pressing unit 3 is fixed to the gate-shaped frame 300 above the substrate stage 2, and a bonding head 4 is linked to a vertical drive shaft of the elevating and pressing unit 3, constituting a mounting means (processing means). In addition, a chip conveyance means 6 for conveying the chip component C to the bonding head 4, and a recognition mechanism 5 for acquiring the respective position information of the chip component C and the substrate at the time of alignment thereof, constitute the mounting device 1.

In order to further explain each constituent element shown in FIG. 1, FIG. 2 shows a configuration in which the gate-shaped frame 300 is omitted from the drawing. An explanation is given below with reference to FIG. 2.

The substrate stage 2 is composed of a stage movement mechanism 20 and a suction table 23. The suction table 23 uses suction to hold a substrate placed on the surface thereof, and the suction table 23 can be moved by the stage movement mechanism 20 in the in-plane direction of the substrate surface while holding the substrate. That is, in the present embodiment (because the elevating and pressing unit 3, which constitutes the mounting means, is fixed), the stage movement mechanism 20 is a mounting position movement mechanism (processing position movement mechanism) that can sequentially move a plurality of mounting locations provided on the substrate to directly below the bonding head 4.

The stage movement mechanism 20 is composed of a Y direction stage movement means 22 that is capable of moving the suction table 23 linearly in the Y direction, and an X direction stage movement means 21 that is provided on the base 200 and is capable of moving the Y direction stage movement means 22 linearly in the X direction. The Y direction movement means 22 has a movable portion that is disposed on a slide rail and on which the suction table 23 is mounted, and the movement and position of the movable portion are controlled by a Y direction servo 221, but the movement can be prevented by operating a Y direction clamp 222. The X direction movement means 21 has a movable portion that is disposed on a slide rail and on which the Y direction movement means 22 is mounted, and the movement and position of the movable portion are controlled by an X direction servo 211, but the movement can be prevented with clamping force by operating an X direction clamp 212. The X direction servo 211 and the Y direction servo 221 are servo motors.

The X direction clamp 212 and the Y direction clamp 222 are braking means that clamp the slide rails to prevent movement in the sliding direction by means of clamping force. It should be noted that a plurality of the X direction clamps 212 and the Y direction clamps 222 may be provided on the slide rails.

In addition, a linear encoder, which is a length measurement means for measuring the amount of movement, may be provided along the slide rails for both the X direction stage movement means 21 and the Y direction stage movement means 22, but it is preferable to provide at least one position detection unit for each of the X direction clamp 212 and the Y direction stage movement means 22, immediately adjacent to the linear encoder.

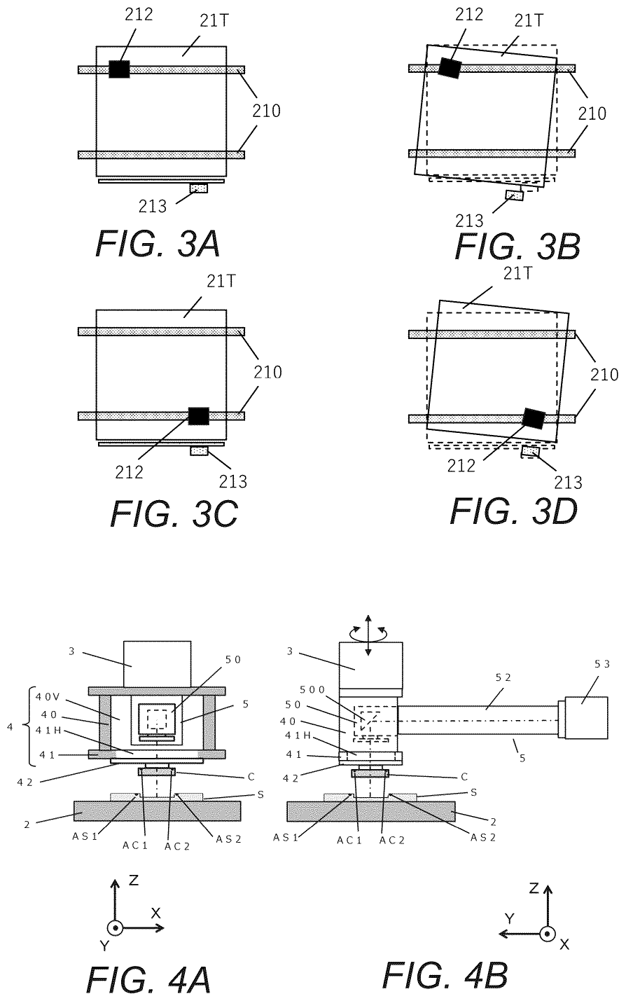

The reason for the foregoing will be described with reference to FIGS. 3A, 3B, 3C and 3D, using the X direction movement means 21 as an example. In FIGS. 3A, 3B, 3C and 3D, the X direction clamp 212 clamps X direction slide rails 210, thereby suppressing the X direction movement of a table 21T, which constitutes the X direction stage movement means 21. In addition, an X direction scale head 213, which is the position detection unit of the linear encoder, is fixed to the table 21T at a position along the X direction slide rails 210 and provides X direction position information. Here, even if the X direction clamp 212 and the X direction scale head 213 are located away from each other, it suffices if the X direction clamp 212 is driven and placed in the state shown in FIG. 3A. However, there may be cases in which fluctuation occurs in the table 21T about the X direction clamp 212 at the time of clamping, such as that shown in FIG. 3B, thereby generating deviation in the X direction position information that is provided by the X direction scale head 213. This deviation is slight, but the X direction servo 211 may oscillate in an attempt to correct this deviation. On the other hand, as shown in FIG. 3C, if the X direction clamp 212 and the X direction scale head 213 are close to each other, even if the table 21T fluctuates in the same manner as shown in FIG. 3B, deviation in the X direction position information provided by the X direction scale head 213 can be suppressed, and oscillation of the X direction servo 211 can be prevented, as shown in FIG. 3D.

The elevating and pressing unit 3 is fixed to the gate-shaped frame 300 and has a vertical drive shaft provided in a direction perpendicular to the suction table 23, and the bonding head 4 is linked to the vertical drive shaft. The elevating and pressing unit 3 has a function of driving the bonding head 4 up and down, and of applying pressure according to a setting. In addition, with the mounting device 1, the elevating and pressing unit 3 is supported from two directions, and the elevating and pressing unit 3 is linked linearly to the bonding head 4, so lateral force is less likely to be applied to the bonding head 4 during pressure application.

The bonding head 4 holds and pressure-bonds the chip component C parallel to the substrate (held by the suction table 23 of the substrate stage 2). The constituent elements of the bonding head 4 include a head body 40, a heater unit 41, an attachment tool 42, and a tool position control means 43. The head body 40 is linked to the elevating and pressing unit 3 via the tool position control means 43, and the heater unit 41 is fixed and disposed on the lower side thereof. The heater unit 41 has a heat generating function, and heats the chip component C through the attachment tool 42. In addition, the heater unit 41 has a function of using suction to hold the attachment tool 42, using a reduced-pressure channel. The attachment tool 42 uses suction to hold the chip component C, and is replaced to match the shape of the chip component C. The tool position control means 43 finely adjusts the position of the head body 40 in the in-plane direction perpendicular to the vertical drive shaft of the elevating and pressing unit 3, and the positions of the attachment tool 42 and the chip component C held by the attachment tool 42 (within the XY plane in the drawings) are adjusted accordingly.

The constituent elements of the tool position control means 43 include an X direction tool position control means 431, a Y direction tool position control means 432, and a tool rotation control means 433. In the embodiment shown in FIG. 2, the configuration is such that the tool rotation control means 433 adjusts the rotation direction of the head body 40, the Y direction tool position control means 432 adjusts the Y direction position of the tool rotation control means 433, and the X direction tool position control means 431 adjusts the X direction position of the Y direction position control means, but this is not the only option, so long as the X direction position, the Y direction position, and the rotation angle of the head body 40 (and any lower constituent elements) can be adjusted. The maximum movable range of the tool position control means 43 is preferably about ±1.0 mm in each direction, but one in which the maximum movable range is about ±5.0 mm may be used, provided that use is limited to an operating range of ±1.0 mm. However, care must be taken because if the maximum movable range is large and usage occurs at the upper limit of the movable range, problems are likely to occur due to misalignment of the center of pressure application below the head body 40 relative to the vertical drive shaft of the elevating and pressing unit 3.

FIGS. 4A and 4B mainly show the periphery of the head body 40 (FIG. 4A is a front view, and FIG. 4B is a side view), but in the face-up mounting of the present embodiment, chip recognition marks AC (first chip recognition mark AC1 and second chip recognition mark AC2) are provided at diagonally opposite locations of the electrode surface of the chip component C, and substrate recognition marks AS (first substrate recognition mark AS1 and second substrate recognition mark AS2) are provided at guide positions at diagonally opposite mounting locations of the chip component on the electrode surface of the substrate S, with all of the marks facing in the direction of the bonding head 4.

Thus, the mounting device 1 is configured so that the chip recognition marks AC are observed from above (through the bonding head 4), and either the attachment tool 42 is formed from a transparent member or a through-hole is provided that is aligned with the positions of the chip recognition marks AC. In addition, the heater unit 41 either must be made of a transparent member or have an opening so that the chip recognition marks AC can be observed, and in this embodiment, a through-hole 41H is provided, as shown in FIGS. 4A and 4B. Here, through-holes 41H may be provided to line up with the positions of the individual chip recognition marks AC, but the hole is preferably shaped so as to accommodate the entire range of size specifications in order to eliminate the need for replacement due to the shape of the chip component C. In addition, since a space into which an image capture unit 50 of the recognition mechanism 5 can enter is required in order to observe the chip recognition marks AC and/or the substrate recognition marks AS, the bonding head 4 is provided with a head space 40V as shown in FIGS. 4A and 4B in this embodiment. That is, the head body 40 has a structure composed of side plates linked on the heater unit 41 and a top plate linking the two side plates.

The recognition mechanism 5 acquires position information about the chip recognition marks AC and/or the substrate recognition marks AS, which are captured by focusing on the chip recognition marks AC and/or the substrate recognition marks AS (through the bonding head 4, through the attachment tool 42 and the heater unit 41). In the present embodiment, the constituent elements of the recognition mechanism 5 include the image capture unit 50, an optical path 52, and an imaging means 53 linked to the optical path 52.

The image capture unit 50 is disposed at the upper part of the recognition target from which the imaging means 53 acquires an image, and keeps the recognition target within the field of view.

Additionally, the recognition mechanism 5 is configured to be capable of being moved, by a drive mechanism (not shown), in the in-plane direction of the substrate S (and the chip component C) within the head space 40V. Furthermore, the recognition mechanism is preferably able to move in a direction perpendicular to the substrate S (Z direction) so that the focal position can be adjusted. The bonding head 4 is moved perpendicular to the substrate S by the elevating and pressing unit 3, and this operation can be performed independently of the operation of the recognition mechanism 5. Therefore, the head space 40V must be designed in a size such that the recognition mechanism 5 entering the head space 40V will not interfere even if the bonding head 4 moves in the vertical direction.

The chip conveyance means 6 is composed of a conveyance rail 60 and a chip slider 61, and is configured so that the chip slider 61 holds and slides the chip component C supplied from a chip supply unit (not shown) to directly below the attachment tool 42.

Here, the chip supply unit (not shown) places the chip component C at a set position on the chip slider 61. If necessary, the position where the chip component C is placed on the chip slider 61 may be recognized by an imaging means (not shown). Thus, controlling the positions of the chip slider 61 and the chip component C placed on the chip slider 61 allows the chip component C to be transferred within a prescribed range of the attachment tool 42; once the attachment tool 42 is holding the chip component C, the chip slider 61 that has released the chip component C moves to a retracted position.

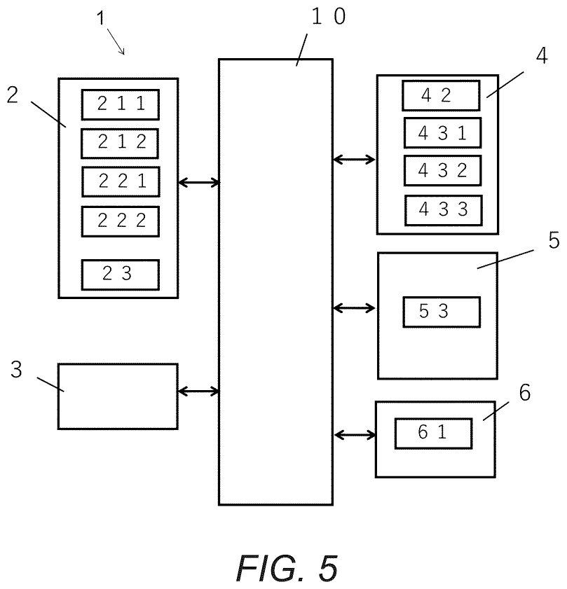

As shown in the block diagram of FIG. 5, the mounting device 1 comprises the substrate stage 2, the elevating and pressing unit 3, the bonding head 4, the recognition mechanism 5, and a control unit 10 connected to the chip conveyance means 6.

Essentially, the main constituent elements of the control unit 10 include a CPU and a storage device, and an interface for each device is included as necessary. In addition, the control unit 10 can have a built-in program to perform calculations using acquired data and to output according to the calculation result.

The control unit 10 is connected to the substrate stage 2 and controls the operations of the X direction servo 211 and the X direction clamp 212 as well as the operations of the Y direction servo 221 and the Y direction clamp 222, and thereby control the in-plane movement of the suction table 23. In addition, the control unit 10 controls the suction table 23 to control the application and release of suction to and from the substrate S.

The control unit 10 is connected to the elevating and pressing unit 3, controls the position of the bonding head 4 in the up and down direction (Z direction), and has the function of controlling the pressure applied when the chip component C is pressure-bonded to the substrate S.

The control unit 10 is connected to the bonding head 4, and has the function of controlling the application and release of suction to and from the chip component C by the attachment tool 42, the heating temperature of the heater unit 41, and the position within the XY plane of the head body 40 (and the heater unit 41 and the attachment tool 42). The control unit 10 is connected to the recognition mechanism 5, controls drive in the horizontal (in the XY plane) direction and the vertical direction (Z direction), and has a function of controlling the imaging means 53 to acquire image data. Furthermore, the control unit 10 has an image processing function, and has a function of calculating the positions of the chip recognition marks AC and/or the substrate recognition marks AS from an image acquired by the imaging means 53.

The control unit 10 is connected to the chip conveyance means 6, and has a function of controlling the position of the chip slider 61 that moves along the conveyance rail 60.

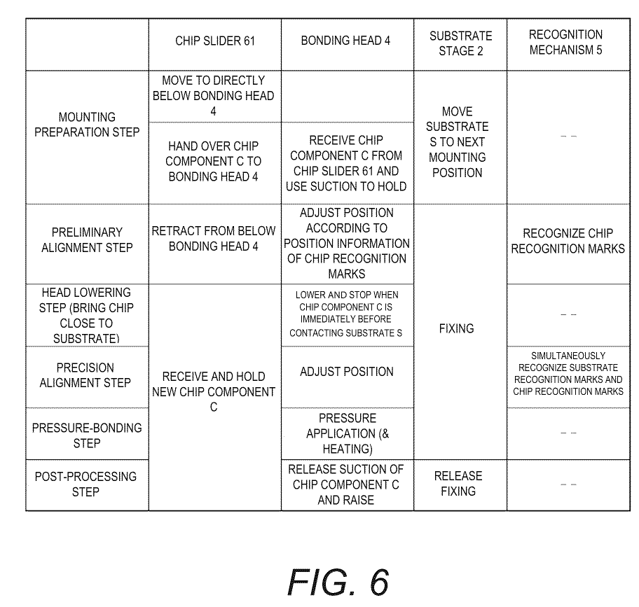

The steps up to when the mounting device 1 mounts the chip component C on the substrate S will be described below, with reference to FIGS. 6 to 9.

FIG. 6 shows a series of steps in the present embodiment shown in conjunction with the state of each constituent element of the mounting device 1. That is, the series of steps are classified into a mounting preparation step, a preliminary alignment step, a head lowering step, a precision alignment step, a pressure-bonding step, and a post-processing step, and the states of the substrate stage 2, the bonding head 4, the recognition mechanism 5, and the chip slider 61 are shown for each step.

The mounting preparation step is a step in which the attachment tool 42 of the bonding head 4 holds the chip component C, and the “mounting location where the chip component C will be mounted next” on the substrate S is disposed directly below the bonding head 4, and it is preferable to increase the positional accuracy of the chip component C held by the attachment tool 42 and the positional accuracy of the “mounting location where the chip component will be mounted next” on the substrate S.

Accordingly, a mechanism that places the chip components C from a chip supply unit (not shown) at prescribed positions on the chip slider 61 with high accuracy, and that conveys the chip slider 61 with the chip conveyance means 6 with high accuracy is employed. In this manner, it is preferable to set the positional accuracy of the chip component C held by the attachment tool 42 to approximately less than or equal to ±50μ.

On the other hand, in order to dispose the “mounting location where the chip component C will be mounted next” on the substrate S directly below the bonding head 4 with high accuracy, it is preferable to employ the stage movement mechanism 20 that accurately controls the position of the suction table 23, and it is preferable that the control unit 10 stores a map of the position of the substrate S on the suction table 23 and of the “mounting location where the chip component C will be mounted next” on the substrate S. The map of the “mounting location where the chip component will be mounted” on the substrate S may be obtained from a wiring pattern layout of the substrate S, or position information may be used, obtained by actually measuring each “mounting location where the chip component will be mounted” on the substrate S on the suction table 23, while moving the recognition mechanism 5 relative to the suction table 23. In this manner, it is preferable to set the positional accuracy of the “mounting location where the chip component C will be mounted next” on the substrate S to approximately less than or equal to ±50μ.

In the mounting preparation step, the stage movement mechanism 20 is used to control the position of the suction table 23 in order to dispose the “mounting location where the chip component C will be mounted next” on the substrate S directly below the bonding head 4, and the X direction servo 211 and the Y direction servo 221 constituting the stage movement mechanism 20 are servo motors, which constantly perform position control when in operation, causing the suction table 23 to vibrate slightly. Although the maximum amplitude of the micro-vibrations of the suction table 23 is about 0.2 μm, it may induce micro-vibrations in other constituent elements, and thus the effects thereof cannot be ignored in a situation in which mounting accuracy of 1 μm or less is required. Furthermore, as will be described further below, because the recognition mechanism 5 moves in the preliminary alignment step, the effects that vibrations generated at the time of this movement have on the position control of the suction table 23 also cannot be ignored.

For this reason, in the mounting preparation step of the present embodiment, the suction table 23 is fixed after the suction table 23 is moved such that the “mounting location where the chip component C will be mounted next” on the substrate S is disposed directly below the bonding head 4. That is, the stage movement mechanism 20 operates the X direction clamp 212 and the Y direction clamp 222 so that the suction table 23 is fixed and prevented from being displaced in the X direction and the Y direction.

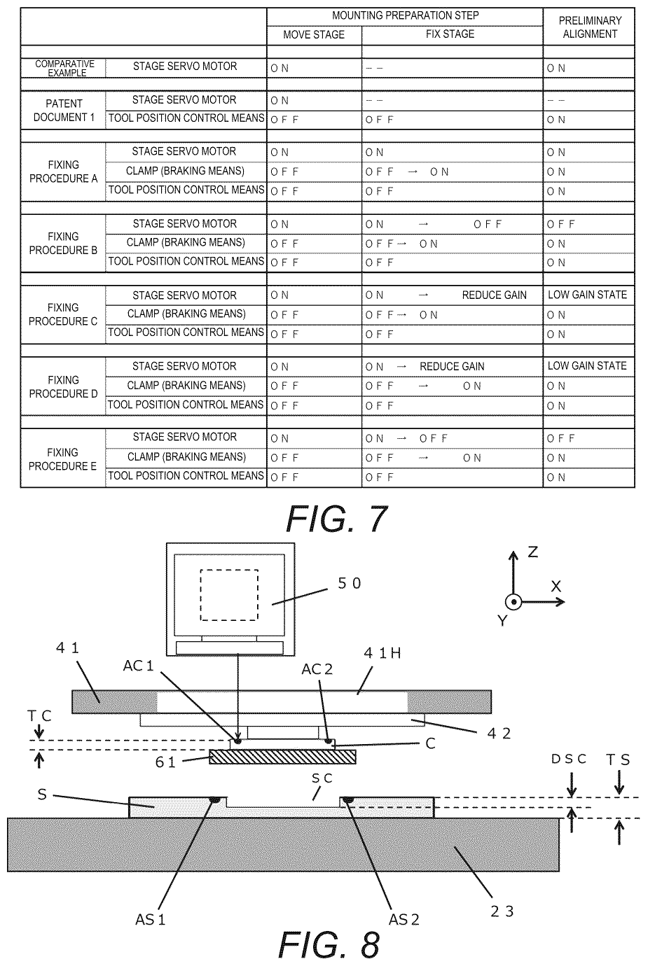

It was revealed that the state of the suction table 23 at the time of fixing differs depending on the timing at which the braking means (X direction clamp 212 and Y direction clamp 222) is operated and the operating state of the servo motors (X direction servo 211 and the Y direction servo 221). Here, the relationship between the operating timing of the braking means and the operating state of the servo motors will be explained, along with the characteristics of each of fixing procedures A to D, shown in FIG. 7. First, in fixing procedure A, the braking means (X direction clamp 212 and Y direction clamp 222) is driven in a state in which the servo motors (X direction servo 211 and Y direction servo 221) are controlling the position of the suction table 23, to fix the position of the suction table 23. That is, the absolute amount of movement of the suction table 23 is set to zero (a value smaller than the required mounting accuracy). Here, even in a state in which the suction table 23 has been moved so as to arrange the “mounting location where the chip component C will be mounted next” on the substrate S, the X direction servo 211 and Y direction servo 221 continue to perform position control with respect to minute displacements, so slight vibrations may be generated immediately after the X direction clamp 212 and Y direction clamp 222 are activated. In addition, the clamp operation itself may generate slight vibrations. Normally, these micro-vibrations tend to settle over time, so it is preferable to provide a timer that would determine that the micro-vibrations of the suction table 23 have settled when a certain amount of time has elapsed after driving the braking means (X direction clamp 212 and Y direction clamp 222). The setting value of the timer is set in accordance with the size and weight of the substrate stage 2, the rating of the servo motor, and the like, but must be 0.1 second or more, and is usually selected from between 0.2 seconds and 0.4 seconds.

In the case of fixing procedure A, if the gain (responsiveness) of the servo motor is high, oscillation may occur as a result of repeatedly attempting position control. Therefore, in order to avoid an oscillating state, power supply to the servo motors (X direction servo 211 and Y direction servo 221) may be turned off after the braking means is driven, as in fixing procedure B shown in FIG. 7. In this fixing procedure B, it is preferable to turn the power supply to the servo motors off after the time (set with the timer) required for the micro-vibrations to dissipate has elapsed, immediately after the braking means is driven. By turning off the power supply to the servo motors in this manner, it is possible to eliminate vibrations caused by the substrate stage 2. Therefore, vibrations of the substrate stage 2 would not induce micro-vibrations in the bonding head 4 or the recognition mechanism 5. However, immediately after the power supply to the servo motors is turned off, the attitude may be disrupted, generating micro-vibrations in other mechanical elements (other axes), so it is preferable to set the timer in accordance with the dissipation time of these micro-vibrations. This timer setting value may be set by actually measuring the time required for the micro-vibrations, generated when the power supply to the servo motors is turned off, to dissipate, and is usually selected from between 0.2 seconds and 0.4 seconds.

The time between when the braking means is driven and the suction table 23 is fixed is longer for fixing procedure B than for fixing procedure A, so fixing procedure B is disadvantageous from the viewpoint of takt time.

Therefore, fixing procedure C shown in FIG. 7 was derived as a procedure that would not be disadvantageous in terms of takt time, while preventing oscillation caused by the servo motors. That is, servo parameters, which are usually adjusted to swiftly move the suction table 23 with good responsiveness, are changed to reduce responsiveness when operating the braking means. Here, the servo parameters include those called position control gain, speed control gain, model control gain, and the like. In the method of fixing procedure C, power supply to the servo motors is not turned off, so there is no need for a timer that waits for dissipation of micro-vibrations of other axes caused by turning the power supply to the servo motors off. However, because the servo motors are being operated, the micro-vibrations become slightly larger when compared to fixing procedure B. In addition, the responsiveness of the servo motors is reduced in fixing procedure C, but there are cases in which the dissipation time of the micro-vibrations is shortened if the responsiveness is increased after the braking means is driven, so the responsiveness after the braking means is driven may be selected in accordance with the intended use.

In fixing procedure C, the braking means (X direction clamp 212 and Y direction clamp 222) is driven after which the responsiveness of the servo motors (X direction servo 211 and Y direction servo 221) is reduced, but results similar to those of fixing procedure C are obtained if the braking means is driven after reducing the responsiveness of the servo motors (at the stage when the “location where the chip component C will be mounted next” on the substrate S has been disposed directly below the bonding head 4), as shown in fixing procedure D.

On the other hand, if a procedure is performed in which the power supply to the servo motors is turned off after which the braking means is driven, as in fixing procedure E, the position can be fixed with high precision, but extremely large positional deviations (of several tens of μm) could also occur. We investigated the cause of such large positional deviations and found that, because the power cable for the servo motors has elasticity, some of the elastic force is released when the power supply is turned off, thereby generating displacement. In addition, it was also found that, if another constituent element of the mounting device 1 is being operated when the power supply to the servo motors is turned off, the vibrations of the element also have an effect. Therefore, when employing fixing procedure E, it is necessary to consider what forces will be applied to each section of the substrate stage 2 when the power supply to the servo motors is turned off.

In the mounting preparation step described above, the “location where the chip component C will be mounted next” on the substrate S is disposed directly below the bonding head 4. For this reason, in the subsequent preliminary alignment step, only the position information of the chip component C is acquired by the recognition mechanism 5, under the assumption that the “location where the chip component C will be mounted next” on the substrate S is present within a prescribed range directly below the bonding head 4.

FIG. 8 illustrates the preliminary alignment step. The preliminary alignment step is performed in a state in which the chip component C is held by the attachment tool 42, but since the recognition mechanism 5 observes only the chip recognition marks AC, the position information of the chip component C can be obtained even when the chip slider 61 that has handed over the chip component C to the attachment tool 42 is in the process of being retracted, as shown in FIG. 8. When the recognition mechanism 5 recognizes the chip recognition marks AC, the second chip recognition mark AC2 is recognized after the first chip recognition mark AC1 is recognized, as shown in FIG. 8. For this reason, the recognition mechanism 5 is moved within the XY plane such that the image capture unit 50 is aligned with each of the marks.

In the preliminary alignment step, the first chip recognition mark AC1 and the second chip recognition mark AC2 are recognized, and the control unit 10 calculates the position information of the chip component C. Here, if the position of the chip component C with respect to the “mounting location where the chip component C will be mounted next” is within a prescribed error range, and the chip slider 61 is in the retracted state, the process proceeds to the subsequent head lowering step. If the position of the chip component C with respect to the “mounting location where the chip component C will be mounted next” is outside of the prescribed error range, the tool position control means 43 is driven to carry out alignment. It is necessary to set the allowable error range for the position of the chip component C such that, when performing the precision alignment step, described further below, at least the first chip recognition mark AC1 and the first substrate recognition mark AS1 (second chip recognition mark AC2 and second substrate recognition mark AS2) fall within the same field of view. Specifically, the numerical value must be less than or equal to ±100 μm, but more preferably less than or equal to ±50 μm.

After the preliminary alignment step, the head lowering step is performed, as shown in FIG. 6. In the head lowering step, the elevating and pressing unit 3 lowers the bonding head 4, and the chip component C is brought as close as possible to the substrate S without coming into contact. The distance between the substrate S and the chip component C is preferably set such that both the first chip recognition mark AC1 and the first substrate recognition mark AS1 (as well as the second chip recognition mark AC2 and the second substrate recognition mark AS2) are within the depth of field of the recognition mechanism 5.

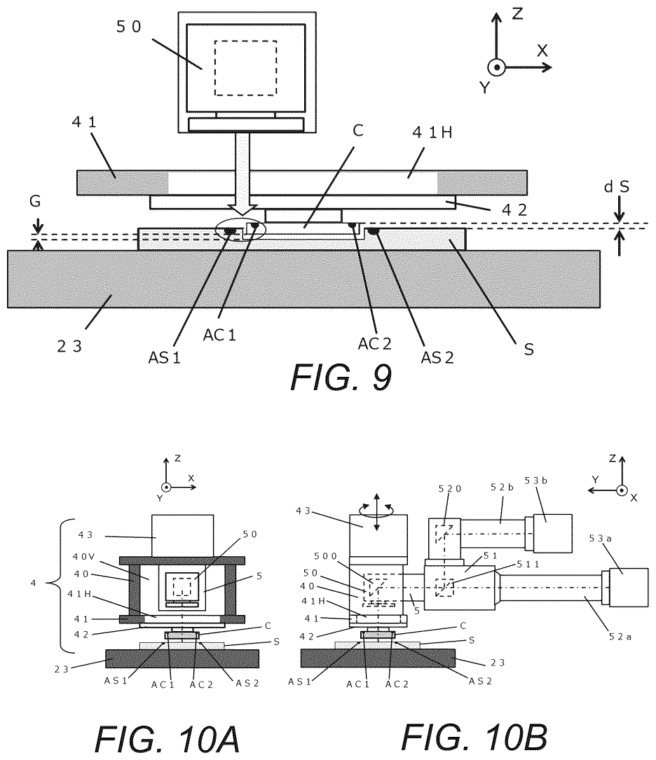

Subsequent to the head lowering step is the precision alignment step. As shown in FIG. 9, in the precision alignment step, the first substrate recognition mark AS1 and the first chip recognition mark AC1 are recognized simultaneously within the same field of view to determine the positional relationship therebetween, but in order to improve accuracy, it is preferable to move the image capture unit 50 to also obtain the positional relationship between the second substrate recognition mark AS2 and the second chip recognition mark AC2. On the basis of the positional relationship between the first substrate recognition mark AS1 and the first chip recognition mark AC1 (as well as the positional relationship between the second substrate recognition mark AS2 and the second chip recognition mark AC2) obtained above, the control unit 10 calculates the amount of positional misalignment between the mounting position of the substrate S and the chip component C, and drives the tool position control means 43 to perform alignment so as to correct the positional misalignment. The tool position control means 43 has an extremely small movable range as compared with the stage movement mechanism 20, and the servo motor thereof is also small, so that there are no vibrations that would affect positional accuracy.

The forgoing completes the precision alignment step, which is followed by the pressure-bonding step. In the pressure-bonding step, the elevating and pressing unit 3 lowers the bonding head 4, and a prescribed amount of pressure is applied to mount the chip component C, when the chip component C has come into close contact with the substrate S, or the heater unit 41 may be heated to perform thermocompression bonding. After pressure application of a prescribed period of time, the pressure-bonding step ends, which is followed by the post-processing step. In the post-processing step, suction of the chip component C by the attachment tool 42 is released and the bonding head 4 is raised, while the fixing of the suction table 23 by the braking means (X direction clamp 212 and Y direction clamp 222) is released. Before releasing the fixing by the braking means, the servo parameters of the servo motors (X direction servo 211 and Y direction servo 221) are returned to the original state (responsiveness is returned to the original state).

If there is a chip component C to be newly mounted after the post-processing step, the mounting preparation step is started.

The foregoing is the series of mounting steps in the present embodiment. In the present embodiment, the chip component C and the “mounting location where the chip component C will be mounted next” on the substrate S are placed with high precision prior to the preliminary alignment step, so that the tool position control means 43 is rarely operated in the preliminary alignment step and the takt time is shortened, resulting in a mounting device with excellent productivity.

However, in order to satisfy the high precision required before the preliminary alignment step, it is necessary to precisely machine and assemble each component of the mounting device, which increases the device cost. Thus, FIGS. 10A and 10B show a configuration of a mounting device, which is a modified example of the present embodiment, that is capable of handling cases in which the precision of the “mounting location where the chip component C will be mounted next” on the substrate S as well as that of the chip component C before the preliminary alignment step exceeds several tens of μm.

Unlike the mounting device 1 shown in FIGS. 4A and 4B, in the mounting device shown in FIGS. 10A and 10B, the constituent elements of the recognition mechanism 5 include the image capture unit 50, an optical system (shared) 51, an optical path 52a and an optical path 52b that branch in two from the optical system 51 with a shared optical axis, an imaging means 53a linked to the optical path 52a, and an imaging means 53b linked to the optical path 52b.

In addition, by providing the “path from the image capture unit 50 to the optical system 51 and the optical path 52a” and the “path from the image capture unit 50 to the optical system 51 and the optical path 52b” so as to have different optical path lengths results in a configuration in which the focal position of the imaging means 53a and the focal position of the imaging means 53b are different. Here, the optical system (shared) 51 has a function of changing the direction of the optical path by a reflecting means 500 and a reflecting means 520, and the optical path is branched by a half mirror 511. The optical path 52a and the optical path 52b each have an optical lens and a function of enlarging an image in order to obtain high resolution.

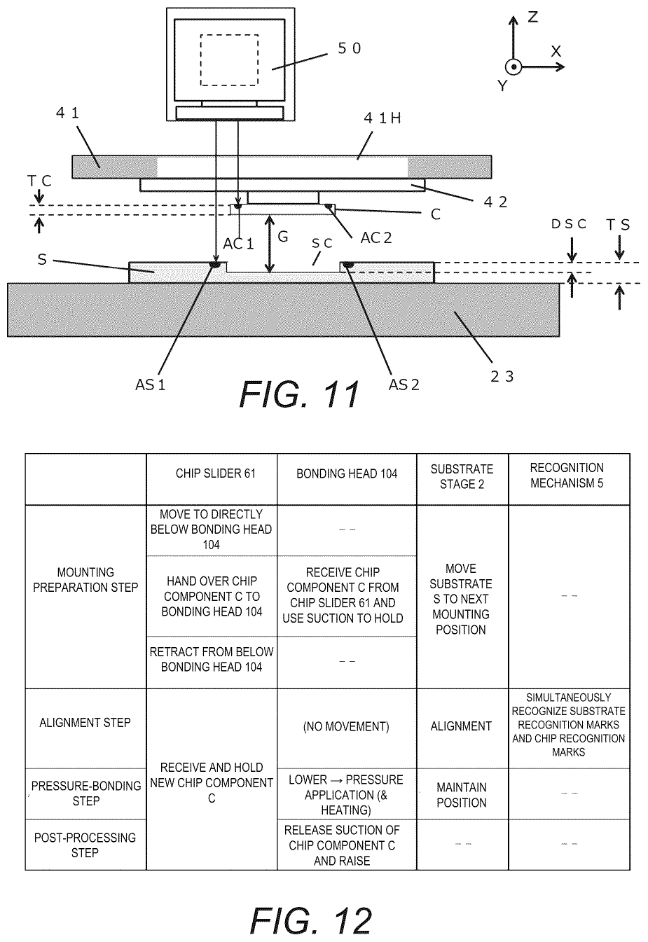

Therefore, as shown in FIG. 11, in the preliminary alignment step, it is possible to simultaneously recognize, and determine the positional relationship between, the first substrate recognition mark AS1 and the first chip recognition mark AC1 (as well as the second substrate recognition mark AS2 and the second chip recognition mark AC2), to perform the alignment. That is, alignment is facilitated if the first substrate recognition mark AS1 and the first chip recognition mark AC1 (as well as the second substrate recognition mark AS2 and the second chip recognition mark AC2) can be imaged on the same optical axis. The preliminary alignment step of the present modified example cannot be started unless the chip slider 61 is in the retracted state. In addition, in the precision alignment of the present modified example, it is sufficient to use either the imaging means 53a or the imaging means 53b to image the first substrate recognition mark AS1 and the first chip recognition mark AC1 (as well as the second substrate recognition mark AS2 and the second chip recognition mark AC2). The operation of the mounting device of the present modified example is the same, except that, in the preliminary alignment step of FIG. 6, the recognition mechanism 5 recognizes the substrate recognition marks AS in addition to the chip recognition marks AC.

In the case of a mounting device 100 as shown in FIG. 20, the alignment step is performed by operating the substrate stage 2, as shown in FIG. 12. In contrast, when operating the mounting device of the present disclosure, both the preliminary alignment step and the precision alignment step can be performed in a state in which the (suction table 23 of the) substrate stage 2 is fixed.

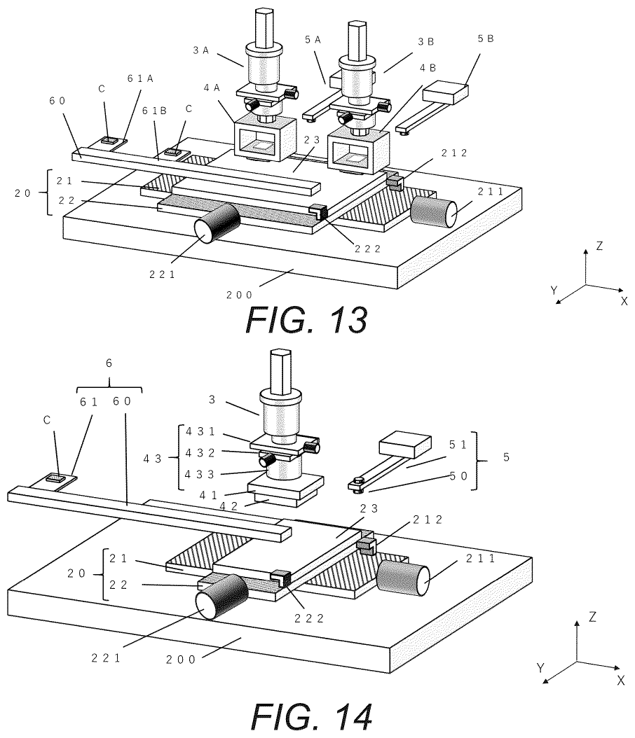

By providing a plurality of bonding heads 4 (as well as corresponding elevating and pressing units 3 and recognition mechanisms 5) at intervals that are several times the mounting pitch, a plurality of chip components C can be mounted simultaneously on one suction table 23. FIG. 13 shows one example thereof, in which a head A having an elevating and pressing unit 3A and a bonding head 4A, and a head B having an elevating and pressing unit 3B and a bonding head 4B are provided. In addition to improving mounting productivity by simultaneously mounting a plurality of chip components C, it becomes possible to perform mounting in a wide area relative to the movable range of the suction table 23. Therefore, the movable range of the suction table 23 can be reduced in size, making it suitable as a mounting device for large substrates.

The classification of the series of steps shown in FIG. 6 is only for the sake of convenience, and no limitation is imposed thereby. For example, if only the chip recognition marks AC are to be recognized in the preliminary alignment step, the “movement of the substrate S to the next mounting location” using the substrate stage 2 may be completed during the preliminary alignment step, instead of during the mounting preparation step.

In addition, the embodiment described above concerns face-up mounting, but the procedure in which “the position of the suction table is fixed and the attachment tool is moved to perform positional adjustment” of the present disclosure can be applied to face-down mounting, in which the electrode surface of the chip component C is mounted facing the electrode surface of the substrate S. That is, in a mounting device 1001 that performs face-down mounting shown in FIG. 14, chip recognition marks AC and substrate recognition marks AS that face each other can be recognized using an upper and lower two-field camera.

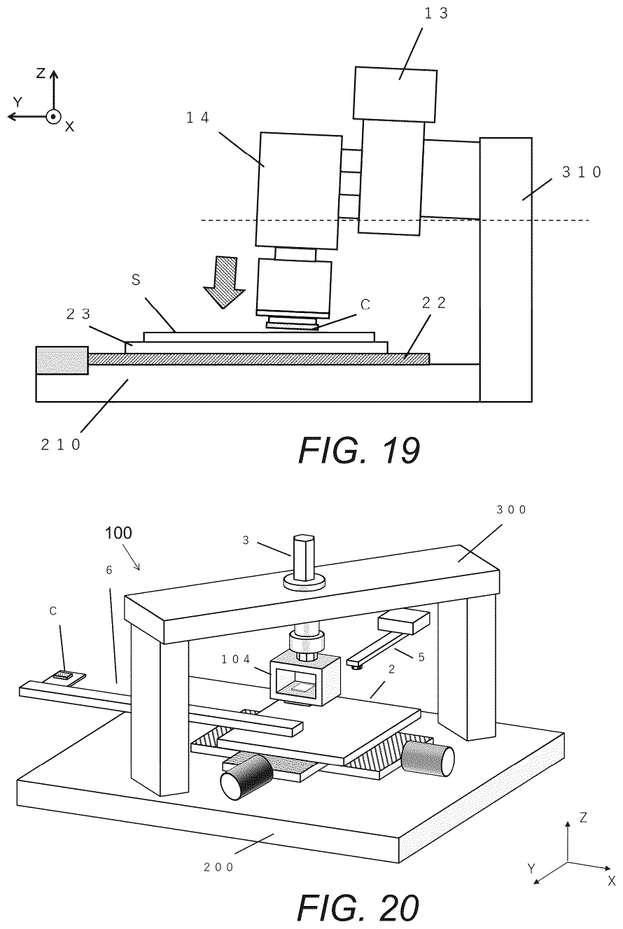

In the foregoing explanation, reference has been made to a device configuration in which the suction table 23 is moved in order to avoid a phenomenon in which the pressurization shaft becomes tilted, as shown in FIG. 19, but with such a device configuration, it is unavoidable that the installation area becomes large. Therefore, there is also demand for a configuration in which the elevating and pressing unit 3 (as well as the bonding head 4) is moved in the in-plane direction of the substrate when handling large substrates.

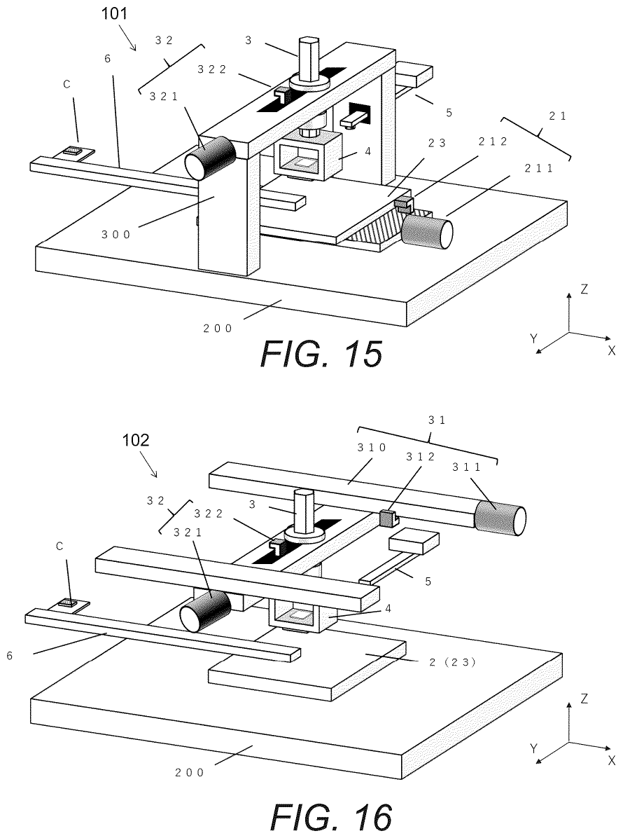

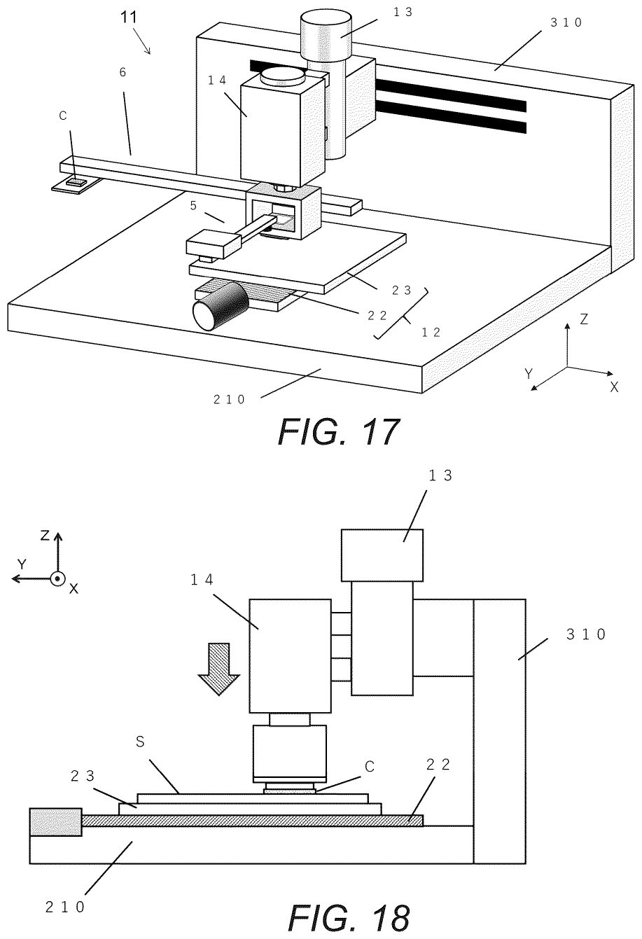

Thus, as shown in FIG. 15, the positioning mechanism may be configured such that the movement of the suction table 23 is limited to one direction (X direction) using the X direction stage movement means 21, which is combined with a Y direction mounting unit movement means 32, which moves the elevating and pressing unit 3 (as well as the linked bonding head 4) in the Y direction of the gate-shaped frame 300.

In the mounting device 101 shown in FIG. 15, the mounting position movement mechanism is formed by a combination of the X direction stage movement means 21 and the Y direction mounting unit movement means 32; even in such a configuration, an X direction clamp 212 serving as a braking means can be provided in the X direction stage movement means 21, and a Y direction clamp 322 serving as a braking means can be provided in the Y direction mounting unit movement means 32, to realize the present disclosure as a second embodiment.

The present disclosure can also be realized as a third embodiment with a mounting device 102 obtained by fixing the suction table 23 and combining the Y direction mounting unit movement means 32, which moves the elevating and pressing unit 3 (as well as the linked bonding head 4) in the Y direction, and an X direction mounting unit movement means 31, which moves the Y direction mounting unit movement means 32 along a rail 310 in the X direction, as shown in FIG. 16. That is, using a mounting unit movement mechanism composed of the Y direction mounting unit movement means 32 and the X direction mounting unit movement means 31 for moving in the X direction as the mounting position movement mechanism, an X direction clamp 312 serving as a braking means may be provided in the X direction mounting unit movement means 31, and the Y direction clamp 322 serving as a braking means may be provided in the Y direction mounting unit movement means 32.

A mounting device for mounting a chip component C on a substrate S has been described above, with respect to a mounting means composed of the elevating and pressing unit 3 and the bonding head 4, and to a configuration for performing positioning of the substrate S, but performance of an attachment process at a prescribed position on the substrate is not limited to mounting. For example, there is great need for accurately positioning the substrate and the processing means in attachment processes such as printing, lamination, and imprint processing. Thus, a positioning device configured to be used when positioning the substrate S and the mounting means in the mounting device of the present disclosure may be used for positioning the substrate and the processing means in such processes as well.

### DESCRIPTIONS OF THE REFERENCE NUMERALS

1 Mounting device
2 Substrate stage
3 Elevating and pressing unit
4 Bonding head
5 Recognition mechanism
6 Chip conveyance means
10 Control unit
20 Stage movement means
21 X direction stage movement means
22 Y direction stage movement means
23 Suction table
31 X direction mounting unit movement means
32 Y direction mounting unit movement means
40 Head body
40V Head space
41 Heater unit
42 Attachment tool
43 Tool position control means
50 Image capture unit
52, 52a, 52b Optical paths
53, 53a, 53b Imaging means
60 Conveyance rail
61 Chip slider
200 Base
210 X direction slide rails
211 X direction servo
212 X direction clamp
221 Y direction servo
222 Y direction clamp
300 Gate-shaped frame
310 Rail
311 X direction servo
312 X direction clamp
321 Y direction servo
322 Y direction clamp
431 X direction tool position control means
432 Y direction tool position control means
433 Tool rotation control means
C Chip component
S Substrate
AC1, AC2 Chip recognition marks
AS1, AS2 Substrate recognition marks

1. A positioning device for determining a relative position between a substrate and a processing unit that is configured to perform an attachment process, when performing the attachment process at a prescribed position of the substrate, comprising:
a substrate table configured to hold the substrate;
a processing position movement mechanism including
a driving unit configured to move the substrate table and the processing unit relative to each other, and
a braking unit configured to restrict movement, caused by the driving unit, of at least one of the substrate table and the processing unit; and
a control unit connected to the driving unit and the braking unit, the control unit being configured to restrict, by using the braking unit, the movement of the at least one of the substrate table and the processing unit during the attachment process.

2. The positioning device according to claim 1, wherein
the processing position movement mechanism has a slide rail,
the driving unit is configured to move the substrate table and the processing unit relative to each other along the slide rail, and
the braking unit restricts movement by partially gripping the slide rail.

3. The positioning device according to claim 2, further comprising
a length measurement unit configured to dispose a position detection unit along the slide rail,
the position detection unit being provided near the braking unit.

4. The positioning device according to claim 1, further comprising
a timer connected to the control unit and configured to measure a time after the braking unit is operated,
the control unit being configured to determine that the attachment process can be started when the time measured by the timer reaches a prescribed value.

5. The positioning device according to claim 1, wherein
the control unit is configured to turn off power supply to the driving unit after operating the braking unit.

6. The positioning device according to claim 1, wherein
the driving unit includes a servo motor, and
the control unit is configured to change responsiveness of the servo motor after operating the braking unit.

7. A mounting device comprising:
the positioning device according to claim 1, wherein
the attachment process is mounting in which a chip component is arranged on the substrate and pressure-bonded, and
the processing unit includes
an attachment tool that is configured to use suction to hold the chip component;
a bonding head that holds the attachment tool; and
an elevating and pressing unit that is linked to the bonding head and is configured to control a position of the bonding head in an up and down direction as well as control pressure.

8. The mounting device according to claim 7, further comprising
a recognition mechanism configured to acquire position information of a substrate recognition mark of the substrate and of a chip recognition mark of the chip component, wherein
the bonding head has a tool position adjustment unit that is configured to finely adjust a position of the attachment tool in an in-plane direction of the chip component, and
in a state in which the bonding head is lowered and the chip component held by the attachment tool is brought close the substrate, after the positioning device determines a relative position of the substrate with respect to the bonding head,
the recognition mechanism acquires the position information of the substrate recognition mark and of the chip recognition mark, and
the tool position adjustment unit precisely aligns the chip component with a mounting location of the substrate.

9. The positioning device according to claim 2, further comprising
a timer connected to the control unit and configured to measure a time after the braking unit is operated,
the control unit being configured to determine that the attachment process can be started when the time measured by the timer reaches a prescribed value.

10. The positioning device according to claim 3, further comprising
a timer connected to the control unit and configured to measure a time after the braking unit is operated,
the control unit being configured to determine that the attachment process can be started when the time measured by the timer reaches a prescribed value.

11. The positioning device according to claim 2, wherein
the control unit is configured to turn off power supply to the driving unit after operating the braking unit.

12. The positioning device according to claim 3, wherein
the control unit is configured to turn off power supply to the driving unit after operating the braking unit.

13. The positioning device according to claim 4, wherein
the control unit is configured to turn off power supply to the driving unit after operating the braking unit.

14. The positioning device according to claim 9, wherein
the control unit is configured to turn off power supply to the driving unit after operating the braking unit.

15. The positioning device according to claim 10, wherein
the control unit is configured to turn off power supply to the driving unit after operating the braking unit.

16. The positioning device according to claim 2, wherein
the driving unit includes a servo motor, and
the control unit is configured to change responsiveness of the servo motor after operating the braking unit.

17. The positioning device according to claim 3, wherein
the driving unit includes a servo motor, and
the control unit is configured to change responsiveness of the servo motor after operating the braking unit.

18. The positioning device according to claim 4, wherein
the driving unit includes a servo motor, and
the control unit is configured to change responsiveness of the servo motor after operating the braking unit.

19. The positioning device according to claim 9, wherein
the driving unit includes a servo motor, and
the control unit is configured to change responsiveness of the servo motor after operating the braking unit.

20. The positioning device according to claim 10, wherein
the driving unit includes a servo motor, and
the control unit is configured to change responsiveness of the servo motor after operating the braking unit.
